(19) United States
(12) Patent Application Publication
(10) Pub. No.: US 2008/0224807 A1
(43) Pub. Date: Sep. 18, 2008

(54) Horizontal magnet arrangement with radial access

(76) Inventors: Francesca Venturini, Duebendorf (CH); Patrick Mock, Uster (CH); Robert Schauwecker, Zuerich (CH)

Correspondence Address: KOHLER SCHMID MOEBUS, RUPPMANNSTRASSE 27, D-70565 STUTTGART, DE

(21) Appl. No.: 12/076,093

(22) Filed: Mar. 13, 2008

(30) Foreign Application Priority Data
Mar. 16, 2007 (DE) 10 2007 013 349.0

(51) Int. Cl. H01F 5/00; G01R 33/381

(52) U.S. Cl. 335/299; 324/319

(57) ABSTRACT

A magnet arrangement comprising a superconducting magnet coil system (M) for generating a magnetic field in the direction of a horizontal z-axis in a working volume (V) disposed along the z-axis about z=0 with at least one radial access to the working volume (V) perpendicular to the z-axis, wherein the magnet coil system comprises at least one partial coil winding (A1a, A1b) disposed coaxially about the z-axis at z>0, and at least one partial coil winding (B1a, B1b) disposed coaxially about the z-axis at z<0, is characterized in that at least one of the partial coil windings (A1a, A1b) at z>0 as well as at least one of the partial coil windings (B1a, B1b) at z<0 are supported by a common coil body (K1), wherein the coil body (K1) has at least one opening (O1) at z=0, which permits radial access to the working volume (V), wherein the coil body (K1) supports the axial magnetic forces between the partial coil windings and wherein the coil body is force-fit mechanically connected to a first side plate (F1) at a front side. This realizes a stable and compact magnet arrangement with radial access.

This application claims Paris Convention priority of DE 10 2007 013 349.0 filed Mar. 16, 2007 the complete disclosure of which is hereby incorporated by reference.

### BACKGROUND OF THE INVENTION

The invention concerns a magnet arrangement comprising a superconducting magnet coil system for generating a magnetic field in the direction of a horizontal z-axis in a working volume disposed along the z-axis about z=0, with at least one radial access to the working volume perpendicular to the z-axis, wherein the magnet coil system comprises at least one partial coil winding disposed coaxially about the z-axis at z>0, and at least one partial winding disposed coaxially about the z-axis at z<0.

A magnet arrangement of this type for NMR experiments is disclosed e.g. in [6].

Horizontal magnet arrangements are used, in particular, for MRI and also for EPR experiments. The magnetic field is thereby generally generated using solenoid coils with horizontal axis (z-axis).

The documents [1]-[6] disclose so-called “split coil” magnet arrangements. They consist of two separate coils or coil systems which are disposed mirror-symmetrically with respect to a plane that is perpendicular to the z-axis. This permits radial access (perpendicular to the z-axis) to the working volume in order to transfer e.g. samples or measuring means into or out of the working volume. The coil systems are separately wound on two or more coil bodies which are held together by a mechanical structure (or a support body) [3, 4]. The documents [4, 5, 6] moreover disclose magnet arrangements whose mechanical structure or support bodies support the axial forces between the two coil systems.

One problem with conventional magnet arrangements consists in that the coil bodies, the flanges and the mechanical structure which hold the coil bodies together must be fixed together in the gap. This reduces the small space available in the gap.

The assembly of the various coil bodies also causes production inaccuracies which, in turn, affect the homogeneity of the magnetic field of the magnet arrangement. One further problem with respect to field homogeneity arises when the actually effective magnetic forces differ from the theoretically calculated values of the design, and the coil systems are displaced with respect to each other.

Moreover, the production becomes complex due to the development of the individual coil systems, the assembly and connection of these coil systems.

It is therefore the purpose of the present invention to propose a magnet arrangement of the above-mentioned type which eliminates these problems.

### SUMMARY OF THE INVENTION

This object is achieved in accordance with the invention in that at least one of the partial coil windings at z>0 as well as at least one of the partial coil windings at z<0 are supported by a common coil body, wherein the coil body has at least one opening at z=0 which permits radial access to the working volume, wherein the coil body supports the axial magnetic forces between the partial coil windings and wherein the coil body is force-fit mechanically connected at a front side to a first side plate.

The partial coil windings of the inventive magnet arrangement are disposed, in particular wound, onto a common coil body. A mechanical structure or a support body for fixing the coil body is not required due to the use of a common coil body. In consequence thereof, no space is required for fixing means. The partial coil windings may therefore be wound directly up to the opening of the coil body, thereby rendering the magnet arrangement particularly compact. In contrast to prior art, the individual parts of the coil body need not be joined, such that these production steps can be omitted. The common coil body moreover provides good heat transfer between the individual partial coil windings. The forces acting on the partial coil windings are advantageously transferred to one single coil body, thereby preventing an undesired movement of different coil body parts relative to each other. The correspondence between the calculated fields and those actually generated is also improved due to the increased mechanical precision.

In a preferred embodiment of the inventive magnet arrangement, the area of the material cross-section of the coil body is at least 5% of a ring area with a surface area (rₐ²−rᵢ²)π in the sectional area perpendicular to the z-axis at z=0, wherein rₐ: largest separation between the outer contour of the material cross-section and the z-axis at z=0, with rₐ>0 and rᵢ: smallest separation between the inner contour of the material cross-section and the z-axis at z=0 with rᵢ>=0. This ensures the required stability of the coil body, at the same time realizing a large opening for radial access.

The coil body is preferably form-fit mechanically connected to a second side plate. The side plates are used to fix the coil body and the partial coil windings disposed thereon to the housing of the magnet arrangement. In contrast to a form-fit mechanical connection of the second side plate, a force-fit connection of the first and also of the second side plate would have static redundancy.

In one particularly preferred embodiment of the inventive magnet arrangement, at least one channel is provided in at least one of the coil bodies for passage of a wire, which connects a first chamber of the coil body containing a partial coil winding at z>0, to a second chamber of the coil body containing a partial coil winding at z<0. In this fashion, the partial coil windings can be wound in one single process. This reduces the number of joints and thus the manufacturing and assembly expenses.

In one particularly preferred embodiment, the magnet coil system comprises at least one additional coil body with at least one radial opening at z=0, wherein the radial openings of the coil bodies are disposed collinearly with respect to each other and permit radial access to the working volume perpendicular to the z-axis. Compensation coils may e.g. be disposed on the second coil body for reducing the stray field of the magnet arrangement, or shim coils may be provided for improving the homogeneity of the overall magnetic field.

In one particular embodiment of this inventive magnet arrangement, two partial coil windings are disposed mirror-symmetrically on each side of the center plane of the coil bodies, wherein the center plane extends through z=0 and is perpendicular to the z-axis. Symmetrically arranged partial coil winding pairs on different coil bodies do not generate any resulting magnetic forces between the coil bodies.

In a particularly advantageous embodiment of this type, at least one of the partial coil windings at z>0 is connected in series with at least one of the partial coil windings at z<0 as a protection section, wherein the protection section is connected in parallel with a common protection element. The protection elements protect the superconducting partial coil coil systems in the respective protection section in case of a quench to prevent an excessive increase of the magnetic forces acting on the superconducting coils. The series connection of the partial coil windings at z>0 with the partial coil windings at z<0 causes maintenance of the symmetric force-free field distribution, even during a quench.

It is also advantageous to provide axial access to the working volume along the z-axis. An axial access may be used e.g. for sample transfer.

The magnet arrangement is advantageously part of an apparatus for electron paramagnetic resonance (EPR) or nuclear magnetic resonance (NMR).

One obtains an overall compact magnet arrangement which can be produced with simplified production methods, and has improved stability and homogeneity properties.

Further advantages of the invention can be extracted from the description and the drawing. The features mentioned above and below may be used individually or collectively in arbitrary combination. The embodiments shown and described are not to be understood as exhaustive enumeration but have exemplary character for describing the invention.

### BRIEF DESCRIPTION OF THE DRAWING

FIG. 1a shows a sectional view of an inventive magnet arrangement along the z-axis;

FIG. 1b shows a three-dimensional broken-out section of an inventive coil body;

FIG. 1c shows a sectional view of the coil body of FIG. 1b perpendicular to the z-axis;

FIG. 2 shows a sectional view of an advantageous embodiment of the inventive magnet arrangement along the z-axis with several coil bodies; and

FIG. 3 shows a wiring diagram of an inventive magnet arrangement.

### DESCRIPTION OF THE PREFERRED EMBODIMENT

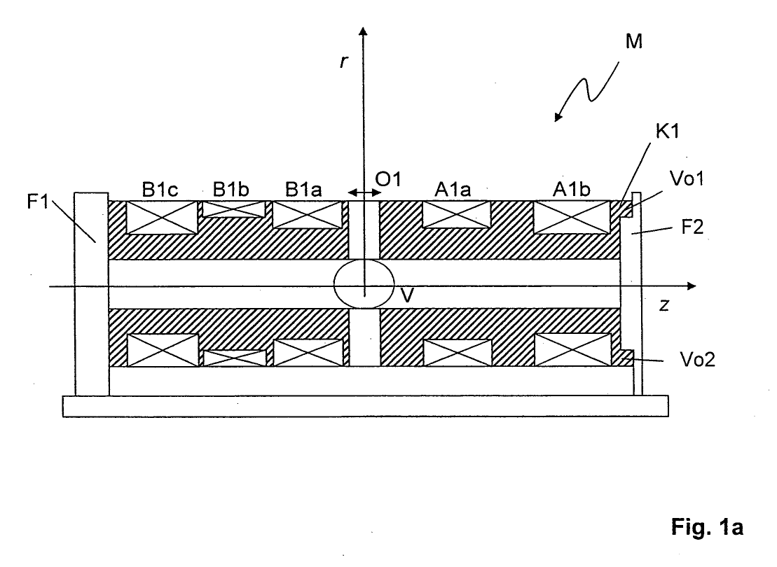

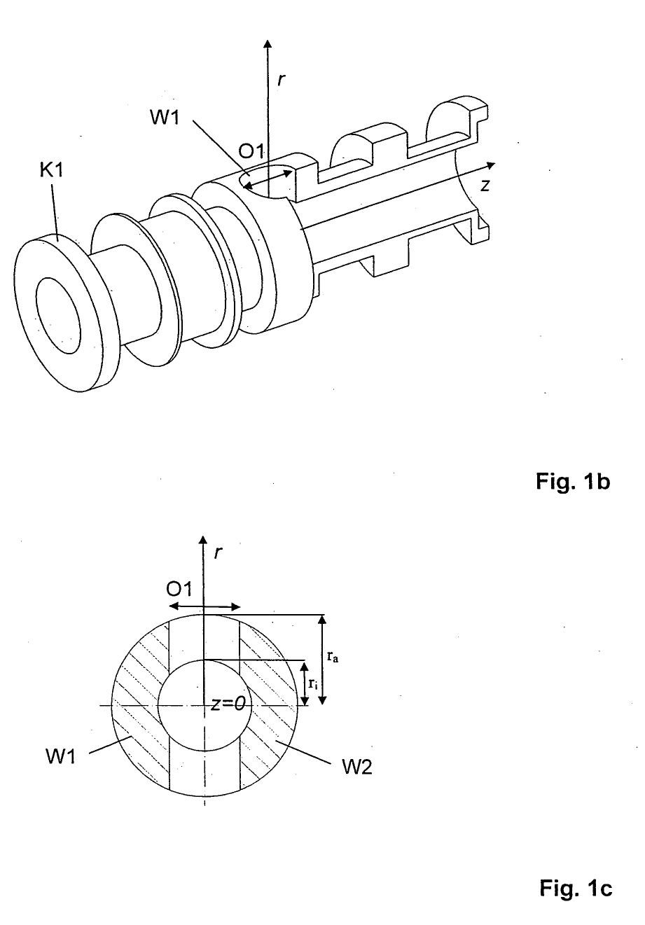

FIG. 1a shows a sectional view of the inventive magnet arrangement M for generating a magnetic field in the direction of a horizontal z-axis. The partial coil windings A1a, A1b, B1c, B1b, B1c are wound onto a rotationally symmetric coil body K1 disposed about the z-axis. The coil body K1 has an opening O1 at z=0 perpendicular to the z-axis. Samples can be transferred through this opening O1 into a working volume V disposed at z=0. The opening O1 may also be used as a passage for measuring means or for irradiating a sample disposed in the working volume V.

The partial coil windings A1a, A1b, B1a, B1b, B1c are distributed along the z-axis, such that part of the partial coil windings A1a, A1b are located in an axial area at z>0, and the other partial coil windings B1a, B1b, B1c in an axial area at z<0. The coil body K1 is used as a support body for the partial coil windings A1a, A1b, B1a, B1b, B1c and the coil body K1 also supports the axial magnetic forces that prevail between the partial coil windings A1a, A1b, B1a, B1b, B1c.

The coil body K1 is force-fit connected to a first side plate F1 at an axial end (front side) of the coil body K1. A second side plate F2 disposed opposite to the first side plate F1 is moreover connected to the coil body K1 through form-fit connection. Towards this end, recesses, in particular millings, are provided on the side of the second side plate F2 facing the first side plate F1, into which the projections Vo1, Vo2 of the coil body K1 engage. The side plates F1, F2 provide a connection to a housing or are themselves part of the housing, as in the present case.

FIG. 1b is a 3-dimensional illustration of the coil body K1 of FIG. 1a. The perspective view clearly shows that the coil body K1 is formed in one piece and has a bore as an opening O1 with lateral walls W1, W2. The coil body K1 has several chambers which are designated for receiving the partial coil windings A1a, A1b, B1a, B1b, B1c, wherein the individual chambers may have different separations from the z-axis. The lateral walls W1, W2 of the coil body K1 in the area of the opening O1 assume the function of conventional support bodies. In contrast to prior art, the inventive magnet arrangement does not require fixing between the coil bodies and the support bodies, since the walls W1, W2 that are used as support bodies are part of the coil body K1 itself. For this reason, the partial coil winding B1a can e.g. be disposed very close to the opening O1, such that the extension of the magnet arrangement M along the z-axis can be reduced compared to prior art.

FIG. 1c shows a sectional view of the coil body K1 of FIG. 1b perpendicular to the z-axis at z=0. At z=0, the coil body K1 has a cross-section in the form of two circular segments of a circular ring with an outer radius rₐ and an inner radius rᵢ. The continuous opening O1 extends along a radial direction r perpendicular to the z-axis and is defined by the lateral walls W1, W2, which represents a connection between the parts of the coil body K1 at z<0 and the parts of the coil body K1 at z<0. An axial access with radius r1 is provided along the z-axis.

In order to guarantee the stability required for supporting the magnetic forces that act on the coil body K1, the area of the cross-section of the walls W1, W2, shown in FIG. 1c, at z=0 is at least 5% of the area of the cross-section at z=0 which would be obtained by rotating the coil body K1 about the z-axis (ring area with inner radius rᵢ and outer radius rₐ).

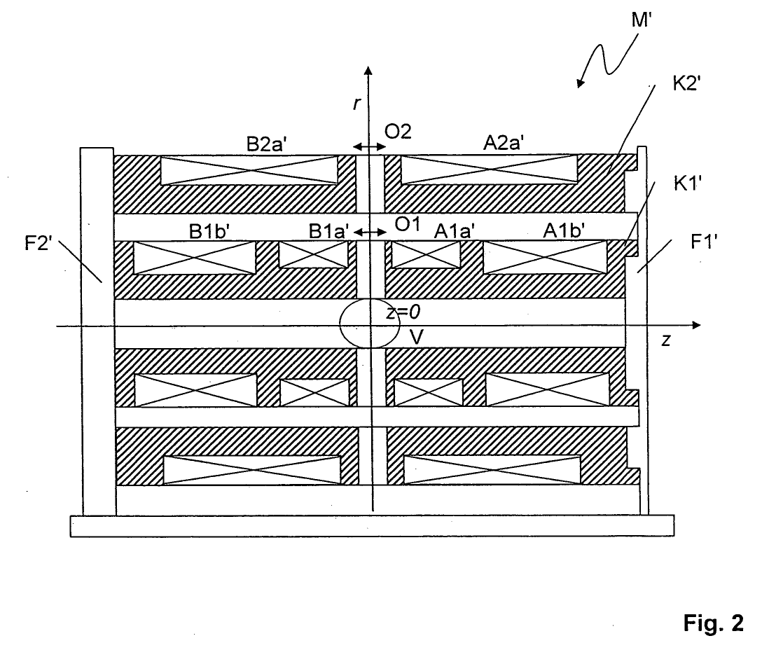

FIG. 2 shows a sectional view of a particularly advantageous embodiment of the inventive magnet arrangement M′ with several coil bodies K1, K2′. Four partial coil windings A1a′, A1b′, B1a′, B1b′ are disposed on the first coil body K1′. The second coil body K2′ is disposed radially outside of the first coil body K1′ and coaxially thereto about the z-axis. Further partial coil windings A2a′, B2a′ are disposed on the second coil body K2′. The second coil body K2′ has an opening O2 at z=0 which is coaxial to the opening O1 of the first coil body K1′ to realize an access to the working volume V through both coil bodies K1′, K2′. The two coil bodies K1′, K2′ are connected to each other through side plates F1′, F2′.

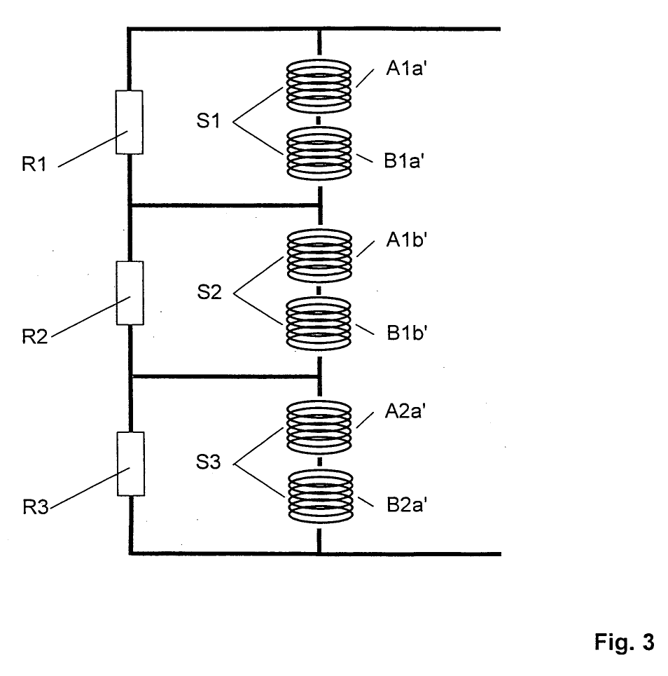

FIG. 3 shows a wiring diagram of an advantageous embodiment of the inventive magnet arrangement M′ with superconducting coils. The partial coil windings A1a′, B1a′, and A1b′, B1b′ and A2a′, B2a′ of the magnet arrangement M′ are serially connected in pairs and form three protection sections S1, S2, S3, each of which comprises one partial coil winding at z>0 and one partial coil winding at z<0. Each protection section S1, S2, S3 is connected in parallel with one of the protection elements R1, R2, R3. The protection elements R1, R2, R3 protect the partial coil windings A1a′, A1b′, B1a′, B1b′, A2a′, B2a′ from overheating and from high electric voltages in case of a breakdown of the superconduction (Quench).

### LIST OF REFERENCE NUMERALS

A1a, A1b partial coil winding at z>0 on coil body K1
A1a′, A1b′ partial coil winding at z>0 on coil body K1′
A2a′ partial coil winding at z>0 on coil body K2′
B1a′, B1b′ partial coil winding at z<0 on coil body K1′
B1a, B1b, B1c partial coil winding at z<0 on coil body K1
B2a′ partial coil winding at z<0 on coil body K2′
F1, F2, F1′, F2′ side plate
K1, K1′, K2′ coil bodies
M, M′ magnet coil system
O1, O2 opening
R1, R2, R3 protection element
rₐ outer radius of the coil body K1 at z=0
rᵢ inner radius of the coil body K1 at z=0
S1, S2, S3 protection section
V working volume
Vo1, Vo2 projection
W1, W2 lateral walls

### LIST OF REFERENCES

[1] US2006125478
(2) US2005253586
[3] Oxford UHV Nanostat (Brochure on website: http://www.oxford-instruments.com/wps/wcm/resources/file/eb73224aa540f1a/UHVNa nostat.pdf)
[4] US2002145426
[5] E. T. Laskaris et al., IEEE Transactions on Applied Superconductivity, Vol. 5, No. 2, June 1995, pages 163-168
[6] US2005134414
[7] JP11312606

1. A magnet arrangement having a superconducting magnet coil system for generating a magnetic field along a horizontal z-axis in a working volume disposed along the z-axis about z=0, the magnet arrangement having at least one radial access to the working volume which is perpendicular to the z-axis, the magnet coil system comprising:
a first coil body having at least one first opening at z=0 to permit radial access to the working volume;
a first side plate mechanically connected to a front side of said coil body in a force-fit manner;
at least one first partial coil winding disposed coaxially about the z-axis at z>0 and supported by said first coil body; and
at least one second partial coil winding disposed coaxially about the z-axis at z<0 and also supported by said first coil body,
wherein said first coil body supports axial magnetic forces between said first and said second partial coil windings.

2. The magnet arrangement of claim 1, wherein an area of material cross-section of said first coil body is at least 5% of a ring having a surface area (rₐ²−rᵢ²)π in a sectional area perpendicular to the z-axis at z=0, wherein rₐ is a largest separation between an outer contour of said material cross-section and the z-axis at z=0, with rₐ>0 and rᵢ is a smallest separation between an inner contour of said material cross-section and the z-axis at z=0, with rᵢ>=0.

3. The magnet arrangement of claim 1, wherein said first coil body is form-fit mechanically connected to a second side plate.

4. The magnet arrangement of claim 1, wherein at least one channel is provided in said first coil body for passage of a wire, which connects a first chamber of said first coil body containing said first partial coil windings at z>0, to a second chamber of said first coil body containing one of said second partial coil windings at z<0.

5. The magnet arrangement of claim 1, wherein the magnet coil system comprises at least one second coil body having at least one second radial opening at z=0, wherein said first and said second radial openings of said first and said second coil bodies are disposed collinearly with respect to each other to permit radial access to the working volume, perpendicular to the z-axis.

6. The magnet arrangement of claim 5, wherein two partial coil windings are disposed mirror-symmetrically on each side of a center plane of said first and said second coil bodies, wherein said center plane extends through z=0 and is perpendicular to the z-axis.

7. The magnet arrangement of claim 6, wherein at least one of said first partial coil windings at z>0 is connected in series with at least one of said second partial coil windings at z<0 as a protection section, said protection section being connected in parallel to a common protection element.

8. The magnet arrangement of claim 1, wherein an axial access to the working volume is provided along the z-axis.

9. The magnet arrangement of claim 1, wherein the magnet arrangement is part of an apparatus for electron paramagnetic resonance or nuclear magnetic resonance.
